(19) United States
(12) Patent Application Publication
(10) Pub. No.: US 2019/0333837 A1
(43) Pub. Date: Oct. 31, 2019

(54) FAN-OUT SEMICONDUCTOR PACKAGE

(71) Applicant: SAMSUNG ELECTRONICS CO., LTD., Suwon-si (KR)

(72) Inventors: Seung On KANG, Suwon-si (KR); Seong Chan PARK, Suwon-si (KR); Chul Kyu KIM, Suwon-si (KR); Kee Ju UM, Suwon-si (KR); Myoung Hoon KIM, Suwon-si (KR); Han KIM, Suwon-si (KR)

(73) Assignee: SAMSUNG ELECTRONICS CO., LTD., Suwon-si (KR)

(21) Appl. No.: 16/189,025

(22) Filed: Nov. 13, 2018

(30) Foreign Application Priority Data
Apr. 27, 2018 (KR) 10-2018-0048919

(51) Int. Cl. H01L 23/373; H01L 23/31; H01L 23/498; H01L 23/367; H01L 23/433; H01L 25/10

(52) U.S. Cl. CPC H01L 23/3735; H01L 23/3128; H01L 23/49822; H01L 23/367; H01L 25/0652; H01L 23/49838; H01L 25/105; H01L 2225/1058; H01L 2225/1094; H01L 23/4334

(57) ABSTRACT

A fan-out semiconductor package includes a core member having a through-hole; a semiconductor chip disposed in the through-hole of the core member and having an active surface on which connection pads are disposed and an inactive surface disposed to oppose the active surface; a heat radiating member directly bonded to the inactive surface of the semiconductor chip; an encapsulant encapsulating at least a portion of the semiconductor chip; and a connection member disposed on the active surface of the semiconductor chip and including redistribution layers electrically connected to the connection pads of the semiconductor chip.

### CROSS-REFERENCE TO RELATED APPLICATION(S)

This application claims the benefit of priority to Korean Patent Application No. 10-2018-0048919 filed on Apr. 27, 2018, in the Korean Intellectual Property Office, the disclosure of which is incorporated herein by reference in its entirety.

### TECHNICAL FIELD

The present disclosure relates to a fan-out semiconductor package.

### BACKGROUND

Semiconductor packages have been continuously required to be thinned and lightened in terms of a shape, and have been required to be implemented in a system in package (SiP) form requiring complexation and multi-functionality in terms of a function. One type of package technology suggested to satisfy the technical demand as described above is a fan-out semiconductor package. Such a fan-out semiconductor package has a compact size and may allow a plurality of pins to be implemented by redistributing connection terminals outwardly of a region in which a semiconductor chip is disposed.

In particular, a semiconductor package having a package-on-package (POP) structure, which has recently been developed, requires a structure capable of improving heat radiation characteristics while significantly reducing a thickness of the package.

### SUMMARY

An aspect of the present disclosure may provide a fan-out semiconductor package of which heat radiation characteristics are improved.

In a fan-out semiconductor package, a heat radiating member containing carbon may be directly bonded to an inactive surface of a semiconductor chip.

According to an aspect of the present disclosure, a fan-out semiconductor package may include a core member having a through-hole; a semiconductor chip disposed in the through-hole of the core member and having an active surface on which connection pads are disposed and an inactive surface disposed to oppose the active surface; a heat radiating member directly bonded to the inactive surface of the semiconductor chip; an encapsulant encapsulating at least a portion of the semiconductor chip; and a connection member disposed on the active surface of the semiconductor chip and including redistribution layers electrically connected to the connection pads of the semiconductor chip.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is a schematic cross-sectional view illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a schematic cross-sectional view illustrating an example of a fan-out semiconductor package;

FIGS. 10A through 10C are schematic views of an example of a process of bonding a heat radiating member to a first semiconductor chip;

FIG. 11 is a schematic cross-sectional view illustrating another example of a fan-out semiconductor package;

FIG. 12 is a schematic cross-sectional view illustrating another example of a fan-out semiconductor package;

FIG. 13 is a schematic cross-sectional view illustrating another example of a fan-out semiconductor package;

FIG. 14 is a schematic cross-sectional view illustrating another example of a fan-out semiconductor package; and

FIGS. 15A through 15C are graphs schematically illustrating a heat radiation effect of a fan-out semiconductor package according to an exemplary embodiment.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The present disclosure may, however, be exemplified in many different forms and should not be construed as being limited to the specific embodiments set forth herein. Rather these embodiments are provided so that this disclosure will be thorough and complete, and will fully convey the scope of the disclosure to those skilled in the art.

Electronic Device

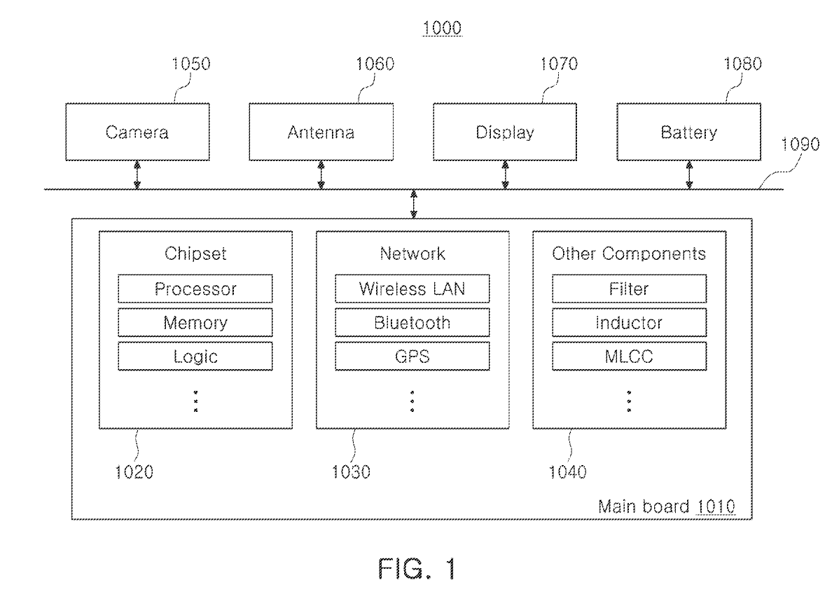

FIG. 1 is a schematic block diagram illustrating an example of an electronic device system.

Referring to FIG. 1, an electronic device 1000 may accommodate a main board 1010 therein. The main board 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter (ADC), an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), and the like. However, other components 1040 are not limited thereto, and may also include passive components used for various other purposes, and the like. In addition, other components 1040 may be combined with each other, together with the chip related components 1020 or the network related components 1030 described above.

Depending on a type of the electronic device 1000, the electronic device 1000 may include other components that may or may not be physically and/or electrically connected to the main board 1010. These other components may include, for example, a camera 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive, or the like. However, the electronic device 1000 is not limited thereto, but may be any other electronic device processing data.

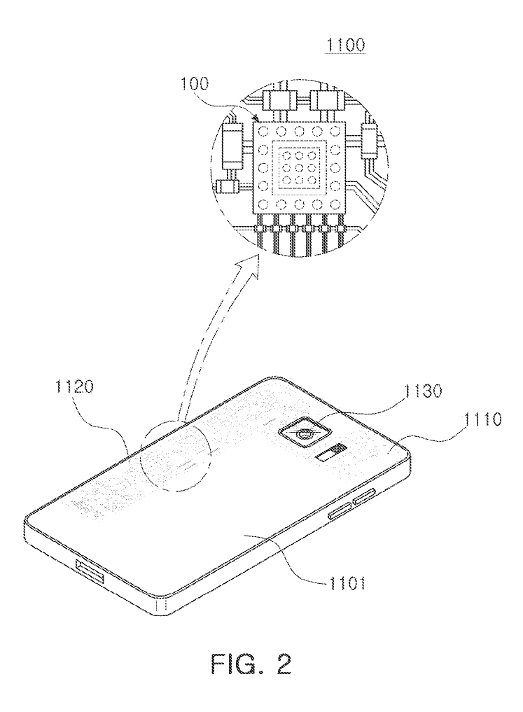

FIG. 2 is a schematic perspective view illustrating an example of an electronic device.

Referring to FIG. 2, a semiconductor package may be used for various purposes in the various electronic devices 1000 as described above. For example, a main board 1110 may be accommodated in a body 1101 of a smartphone 1100, and various components 1120 may be physically or electrically connected to the main board 1110. In addition, other components that may or may not be physically and/or electrically connected to the main board 1110, such as a camera 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a semiconductor finished product in oneself, and may be damaged due to external physical or chemical impact. Therefore, the semiconductor chip is not used in oneself, and is packaged and is used in an electronic device, or the like, in a package state.

The reason why semiconductor packaging is required is that there is a difference in a circuit width between the semiconductor chip and a main board of the electronic device in terms of electrical connection. In detail, a size of connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and packaging technology for buffering a difference in a circuit width between the semiconductor and the main board is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

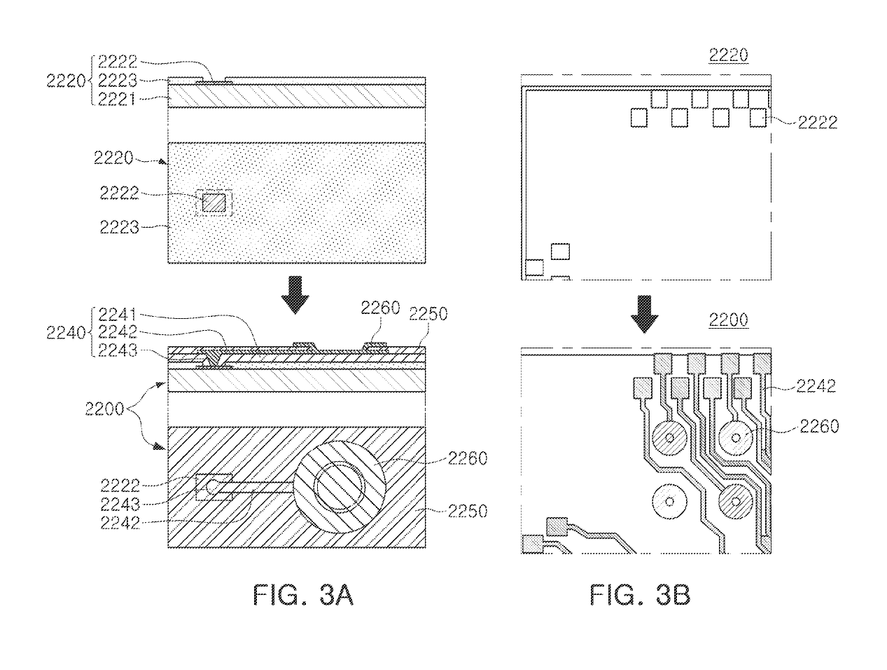

FIGS. 3A and 3B are schematic cross-sectional views illustrating states of a fan-in semiconductor package before and after being packaged.

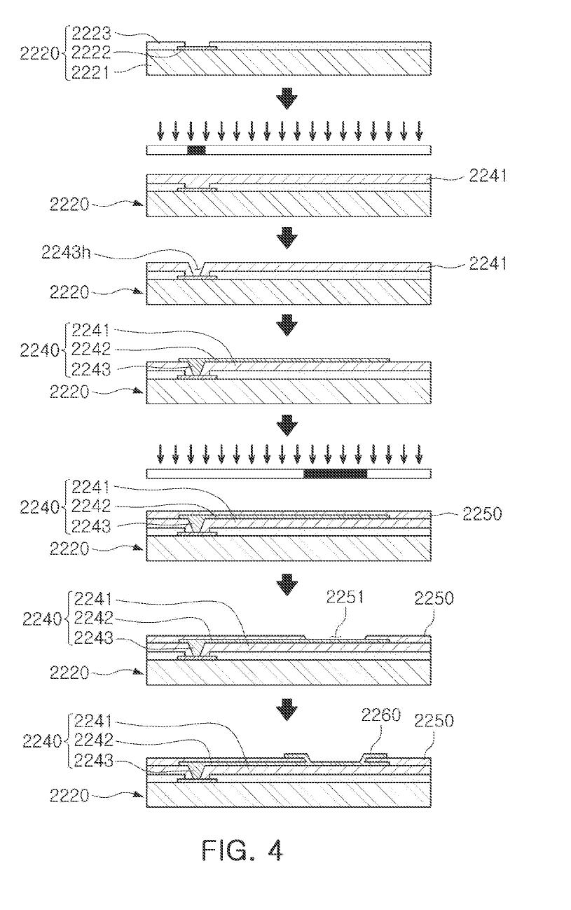

FIG. 4 is a schematic cross-sectional view illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 are significantly small, it is difficult to mount the integrated circuit (IC) on an intermediate level printed circuit board (PCB) as well as on the main board of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a small size. In addition, due to the disadvantage described above, the fan-in semiconductor package may not be directly mounted and used on the main board of the electronic device. The reason is that even in the case that a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the main board of the electronic device.

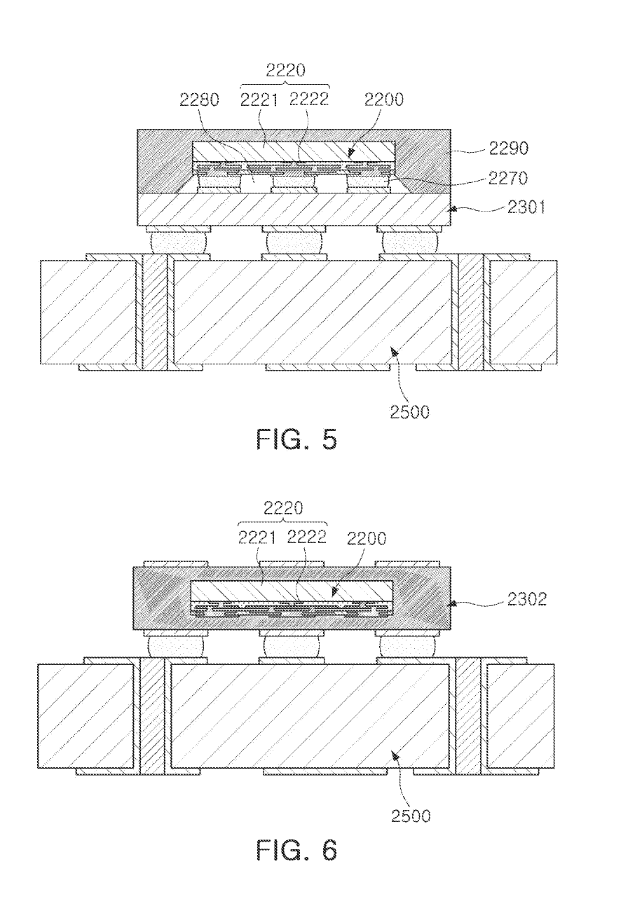

FIG. 5 is a schematic cross-sectional view illustrating a case in which a fan-in semiconductor package is mounted on an interposer substrate and is finally mounted on a main board of an electronic device.

FIG. 6 is a schematic cross-sectional view illustrating a case in which a fan-in semiconductor package is embedded in an interposer substrate and is finally mounted on a main board of an electronic device.

Referring to the drawings, in a fan-in semiconductor package 2200, connection pads 2222, that is, I/O terminals, of a semiconductor chip 2220 may be redistributed once more through an interposer substrate 2301, and the fan-in semiconductor package 2200 may be finally mounted on a main board 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of a semiconductor chip 2220 may be redistributed once more by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

Fan-Out Semiconductor Package

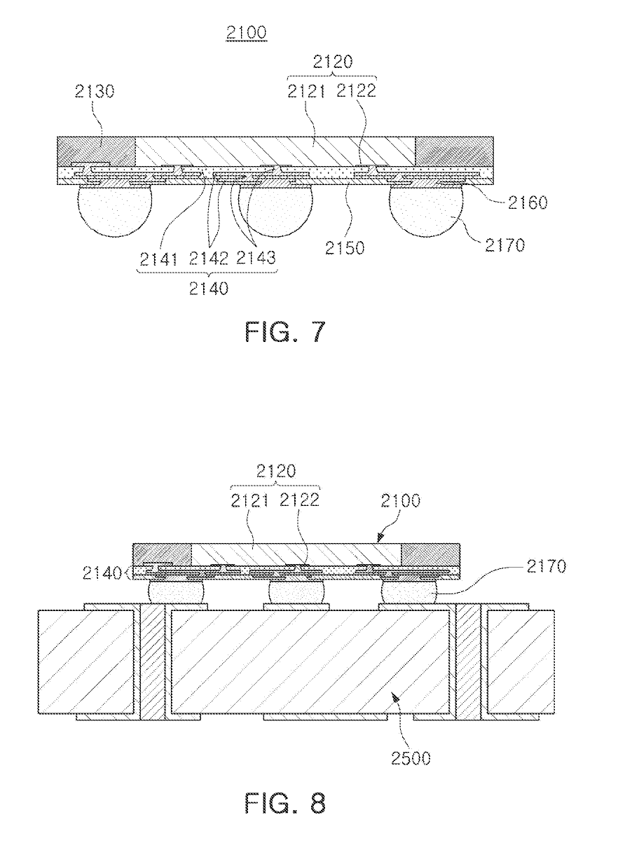

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2202 may be further formed on the connection member 2140, and an underbump metal layer 2160 may be further formed in openings of the passivation layer 2202. Solder balls 2170 may be further formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2241, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in the case that a size of the semiconductor chip is decreased, a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to FIG. 8, a fan-out semiconductor package 2100 may be mounted on a main board 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to occurrence of a warpage phenomenon.

Meanwhile, the fan-out semiconductor package refers to package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

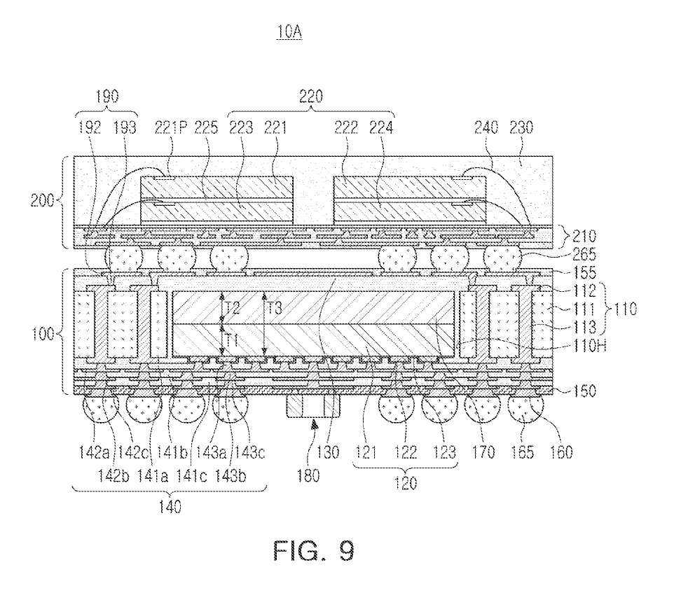

FIG. 9 is a schematic cross-sectional view illustrating an example of a fan-out semiconductor package.

Referring to FIG. 9, a fan-out semiconductor package 10A according to an exemplary embodiment may have a POP structure including a first semiconductor package 100 and a second semiconductor package 200 which are stacked in a vertical direction, and the second semiconductor package 200 may be stacked on the first semiconductor package 100. The first semiconductor package 100 may include a core member 110 having a through-hole 110H, a first semiconductor chip 120 disposed in the through-hole 110H of the core member 110 and having an active surface on which connection pads 122 are disposed and an inactive surface disposed to oppose the active surface, a heat radiating member 170 directly bonded onto the inactive surface of the first semiconductor chip 120 and containing carbon, a first encapsulant 130 encapsulating at least portions of the core member 110 and the first semiconductor chip 120, a connection member 140 disposed on the core member 110 and the active surface of the first semiconductor chip 120, a backside wiring structure 190 disposed on the first encapsulant 130, a passivation layer 150 disposed on the connection member 110, an underbump metal layer 160 disposed on an opening of the passivation layer 150, electrical connection structures 165 disposed on the passivation layer 150 and connected to the underbump metal layer 160, and a passive component 180 disposed on the passivation layer 150. The second semiconductor package 200 may include a wiring substrate 210, a plurality of second semiconductor chips 220 disposed on the wiring substrate 210, a second encapsulant 230 encapsulating the second semiconductor chips 220, and an upper connection terminal 265 below the wiring substrate 210.

Meanwhile, in the case of the POP structure, since the semiconductor chips are stacked in a vertical direction, there is a problem that heat generation is intensified and performance of the semiconductor chips is deteriorated. In particular, in the case of a system on chip (SoC) such as AP, heat is locally generated in a position in which an operation inside the semiconductor chip is performed. Thus, the heat radiation may be effectively achieved by disposing the heat radiating member close to such a heat generation position. In the fan-out semiconductor package 10A according to an exemplary embodiment, the first semiconductor chip 100 as a fan-out semiconductor package may be used to mount a main semiconductor chip 120 such as an AP chip and to mount the semiconductor chip 220 such as a memory chip thereon, and heat radiation characteristics may be secured by disposing the heat radiating member 170 on the first semiconductor chip 120.

The heat radiating member 170 may be formed of a carbon-based material having an excellent heat radiation effect, and may include, for example, at least one of silicon carbide (SiC), graphite, graphene, carbon nanotubes (CNT), and a metal-graphite composite material. Graphene is a two-dimensional carbon hexagonal mesh sheet formed of a single atomic layer of graphite. The heat radiating member 170 may be formed of a material having a difference in a coefficient of thermal expansion (CTE) which is not more than 10 ppm/K with silicon (Si) having the coefficient of thermal expansion of about 2.7 ppm/K. Specifically, the heat radiating member 170 may be formed of a material having the coefficient of thermal expansion in the range of 2 ppm/K to 10 ppm/K, and may be particularly formed of a material having the coefficient of thermal expansion in the range of 3 ppm/K to 9 ppm/K. For example, silicon carbide (SiC) may have the coefficient of thermal expansion of about 3 ppm/K to 6 ppm/K irrespective of crystal structure, graphite may have the coefficient of thermal expansion in the range of about 1 ppm/K to 8 ppm/K, and copper-graphite (Cu-Gr) composite material may have the coefficient of thermal expansion in the range of about 4 ppm/K to 9 ppm/K.

The heat radiating member 170 may be formed of a material capable of preventing an occurrence of warpage by significantly reducing the difference in the coefficient of thermal expansion with the first semiconductor chip 120 which is mainly formed of silicon as described above, and may be formed of a material having thermal conductivity higher than thermal conductivity of about 150 W/mK of silicon. In particular, the heat radiating member 170 may be formed of a material having thermal conductivity in the range of 250 W/mK to 500 W/mK. For example, depending on a crystal structure, silicon carbide (SiC) may have thermal conductivity in the range of about 350 W/mK to 500 W/mK for a single crystal and may have thermal conductivity in the range of 250 W/mK to 300 W/mK, which is lower than thermal conductivity of the single crystal, for a polycrystal. Graphite may have different thermal conductivity depending on a direction, but may have thermal conductivity of about 500 W/mK or more in a horizontal direction, and copper-graphite (Cu-Gr) composite material may have thermal conductivity in the range of about 300 W/mK to 400 W/mK.

The respective components included in the fan-out semiconductor package 10A according to the exemplary embodiment will hereinafter be described in more detail.

The core member 110 may improve rigidity of the first semiconductor package 100 depending on certain materials, and may serve to secure uniformity of a thickness of a first encapsulant 130. In addition, the fan-out semiconductor package 10A according to the exemplary embodiment may be used as a portion of a POP by the core member 110. The core member 110 may have the through-hole 110H. The first semiconductor chip 120 may be disposed in the through-hole 110H to be spaced apart from the core member 110 by a predetermined distance. Side surfaces of the first semiconductor chip 120 may be surrounded by the core member 110. However, such a form is only an example and may be variously modified to have other forms, and the core member 110 may perform another functions, depending on such a form. The core member 110 may be omitted, if necessary, but it may be more advantageous in securing board level reliability intended in the present disclosure in which the fan-out semiconductor package 10A includes the core member 110.

The core member 110 may include a core insulating layer 111, wiring layers 112 disposed on opposite surfaces of the core insulating layer 111, and core vias 113 penetrating through the core insulating layer 111 and connecting upper and lower wiring layers 112 to each other. Therefore, the wiring layers 112 disposed on the opposite surfaces of the core insulating layer 111 may be electrically connected to each other through the core vias 113.

An insulating material may be used as a material of the core insulating layer 111. In this case, the insulating material may be a thermosetting resin such as an epoxy resin, a thermoplastic resin such as a polyimide resin, an insulating material in which the thermosetting resin or the thermoplastic resin is impregnated in a core material such as an inorganic filler and/or a glass fiber (a glass cloth or a glass fabric), for example, prepreg, Ajinomoto Build-up Film (ABF), FR-4, Bismaleimide Triazine (BT), or the like. Such a core member 110 may serve as a support member.

The wiring layers 112 may serve to redistribute the connection pads 122 of the first semiconductor chip 120. A material of each of the wiring layers 112 may be a conductive material such as copper (Cu), aluminum (Al), silver (Ag), tin (Sn), gold (Au), nickel (Ni), lead (Pb), titanium (Ti), or alloys thereof. The wiring layers 112 may perform various functions depending on designs of their corresponding layers. For example, the wiring layers 112 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112 may include via pads, wire pads, connection terminal pads, and the like.

The core vias 113 may electrically connect the wiring layers 112 formed on different layers to each other, resulting in an electrical path in the core member 110. A material of each of the core vias 113 may be a conductive material. Each of the core vias 113 may be entirely filled with the conductive material, or the conductive material may be formed along a wall of each of via holes. In addition, each of the core vias 113 may have any shape known in the related art, such as a tapered shape, a cylindrical shape, and the like.

The first semiconductor chip 120 may be an integrated circuit (IC) provided in an amount of several hundreds to several millions of elements or more integrated in a single chip. The first semiconductor chip 120 may be, for example, a processor chip (more specifically, an application processor (AP)) such as a central processor (for example, a CPU), a graphic processor (for example, a GPU), a field programmable gate array (FPGA), a digital signal processor, a cryptographic processor, a microprocessor, a microcontroller, or the like, but is not limited thereto. That is, the IC may be a logic chip such as an analog-to-digital converter, an application-specific IC (ASIC), or the like, or a memory chip such as a volatile memory (for example, a DRAM), a non-volatile memory (for example, a ROM and a flash memory), or the like, but is not limited thereto. In addition, the above-mentioned elements may also be combined with each other and be disposed.

The active surface of the first semiconductor chip 120 refers to a surface of the first semiconductor chip 120 on which the connection pads 122 are disposed, and the inactive surface thereof refers to a surface opposing the active surface. The first semiconductor chip 120 may be formed on the basis of an active wafer. In this case, a base material of a body 121 may be silicon (Si), germanium (Ge), gallium arsenide (GaAs), or the like. Various circuits may be formed on the body 121. The connection pads 122 may electrically connect the first semiconductor chip 120 to other components, and a conductive material such as aluminum (Al), or the like, may be used as a material of each of the connection pads 122 without being particularly limited. A passivation layer 123 exposing the connection pads 122 may be formed on the body 121, and may be an oxide film, a nitride film, or the like, or a double layer of an oxide layer and a nitride layer. A lower surface of the connection pad 122 may have a step with respect to a lower surface of the first encapsulant 130 through the passivation layer 123. Resultantly, a phenomenon in which the first encapsulant 130 bleeds into the lower surface of the connection pad 122 may be prevented to some degree. An insulating layer (not illustrated), and the like, may also be further disposed in other required positions.

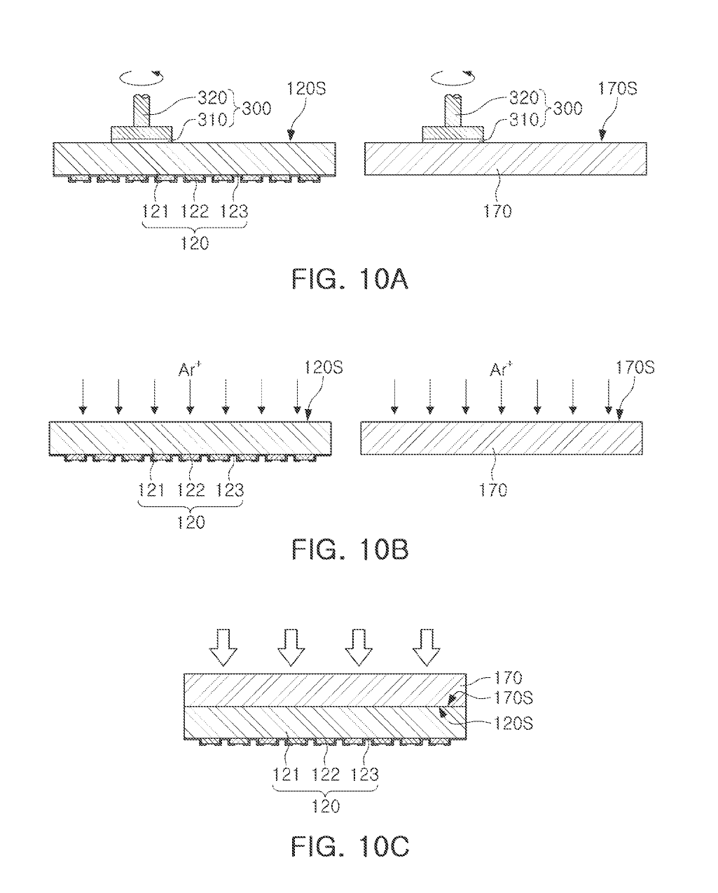

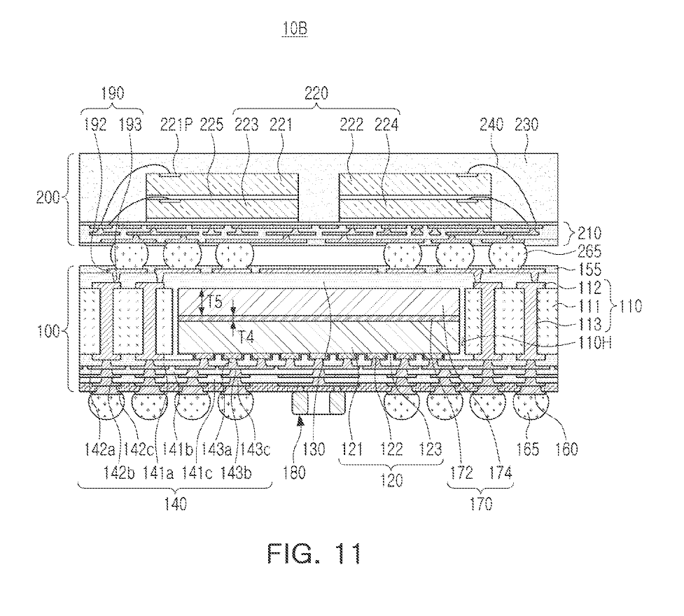

The heat radiating member 170 may be directly bonded to the first semiconductor chip 120. Thus, the heat radiating member 170 may be raised by a thickness of an omitted adhesive layer. The direct bonding will be described in more detail with reference to FIGS. 10A through 10C. Accordingly, the heat radiating member 170 may be in direct contact with the entirety of the inactive surface of the first semiconductor chip 120, and may be disposed in the through-hole 110H together with the first semiconductor chip 120. The heat radiating member 170 may have the same size as that of the first semiconductor chip 120 on a plane. The heat radiating member 170 may have a second thickness T2 which is the same as or smaller than a first thickness T1 of the first semiconductor chip 120. For example, the first and second thicknesses T1 and T2 may each be half of the total thickness T3 of the first semiconductor chip 120 and the heat radiating member 170, but is not limited thereto.

The first encapsulant 130 may protect the core member 110, the first semiconductor chip 120, and the like. An encapsulation form of the first encapsulant 130 is not particularly limited, but may be a form in which the first encapsulant 130 surrounds at least portions of the first semiconductor chip 120. For example, the first encapsulant 130 may cover at least portions of the core member 110 and the inactive surface of the first semiconductor chip 120, and fill at least portions of spaces between walls of the through-hole 110H and side surfaces of the first semiconductor chip 120.

Meanwhile, the first encapsulant 130 may fill the through-hole 110H to thus serve as an adhesive for fixing the first semiconductor chip 120 and reduce buckling of the first semiconductor chip 120 depending on certain materials. A material of the first encapsulant 130 is not particularly limited. For example, an insulating material may be used as the material of the first encapsulant 130. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a PID resin may also be used as the insulating material.

The connection member 140 may redistribute the connection pads 122 of the semiconductor chip 120. Several tens to several hundreds of connection pads 122 of the first semiconductor chip 120 having various functions may be redistributed by the connection member 140, and may be physically and/or electrically externally connected through the electrical connection structures 165 depending on the functions. The connection member 140 may include a first insulating layer 141a disposed on the core member 110 and the active surface of the semiconductor chip 120, a first redistribution layer 142a disposed on the first insulating layer 141a, a first via 143a connecting the first redistribution layer 142a and the connection pads 122 of the semiconductor chip 120 to each other, a second insulating layer 141b disposed on the first insulating layer 141a, a second redistribution layer 142b disposed on the second insulating layer 141b, a second via 143b penetrating through the second insulating layer 141b and connecting the first and second redistribution layers 142a and 142b to each other, a third insulating layer 141c disposed on the second insulating layer 141b, a third redistribution layer 142c disposed on the third insulating layer 141c, and a third via 143c penetrating through the third insulating layer 141c and the connecting the second and third redistribution layers 142b and 142c to each other. The first to third redistribution layers 142a, 142b, and 142c may be electrically connected to the connection pads 122 of the first semiconductor chip 120.

An insulating material may be used as a material of each of the insulating layers 141a, 141b, and 141c. In this case, in addition to the insulating material as described above, a photosensitive insulating material such as a PID resin may also be used as the insulating material. That is, the insulating layers 141a, 141b, and 141c may be photosensitive insulating layers. When the insulating layers 141a, 141b, and 141c has photosensitive properties, the insulating layers 141a, 141b, and 141c may be formed to have a smaller thickness, and fine pitches of the vias 143a, 143b, and 143c may be achieved more easily. The insulating layers 141a, 141b, and 141c may be photosensitive insulating layers including an insulating resin and an inorganic filler. When the insulating layers 141a, 141b, and 141c are multiple layers, the materials of the insulating layers 141a, 141b, and 141c may be the same as each other, and may also be different from each other, if necessary. When the insulating layers 141a, 141b, and 141c are the multiple layers, the insulating layers 141a, 141b, and 141c may be integrated with each other depending on a process, such that a boundary therebetween may also not be apparent. A larger number of insulating layers than those illustrated in the drawing may be formed.

The redistribution layers 142a, 142b, and 142c may serve to substantially redistribute the connection pads 122. A material of each of the redistribution layers 142a, 142b, and 142c may be a conductive material such as copper (Cu), aluminum (Al), silver (Ag), tin (Sn), gold (Au), nickel (Ni), lead (Pb), titanium (Ti), or alloys thereof. For example, a seed metal layer 145a and a plated metal layer 145b forming the redistribution layers 142a, 142b, and 142c may be formed of copper (Cu) or an alloy thereof, and bonded metal layers 144a and 144b may be formed of titanium (Ti) or an alloy thereof. However, a second bonded metal layer 144b may be an optional configuration and may be omitted according to the exemplary embodiments. The redistribution layers 142a, 142b, and 142c may perform various functions depending on designs of their corresponding layers. For example, the redistribution layers 142a, 142b, and 142c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layers 142a, 142b, and 142c may include via pad patterns, electrical connection structure pad patterns, and the like.

The vias 143a, 143b, and 143c may respectively electrically connect the redistribution layers 142a, 142b, and 142c, the connection pads 122, or the like, formed on different layers to each other, resulting in an electrical path in the fan-out semiconductor package 10A. A material of each of the vias 143a, 143b, and 143c may be a conductive material such as copper (Cu), aluminum (Al), silver (Ag), tin (Sn), gold (Au), nickel (Ni), lead (Pb), titanium (Ti), or alloys thereof. For example, the seed metal layer 145a and the plated metal layer 145b forming the vias 143a, 143b, and 143c may be formed of copper (Cu) or an alloy thereof, and the bonded metal layers 144a and 144b may be formed of titanium (Ti) or an alloy thereof. Each of the vias 143a, 143b, and 143c may be entirely filled with the conductive material, or the conductive material may also be formed along a wall of each of the vias. In addition, each of the vias 143a, 143b, and 143c may have all of the shapes known in the related art, such as a tapered shape, a cylindrical shape, and the like.

The backside wiring structure may include backside redistribution layers 192 disposed on the first encapsulant 130 and backside vias 193 penetrating through the first encapsulant 130. The backside vias 193 may connect the backside redistribution layers 192 and the core vias 113 of the core member 110 to each other. A material of each of the backside redistribution layers 192 and the backside vias 193 may be a conductive material such as copper (Cu), aluminum (Al), silver (Ag), tin (Sn), gold (Au), nickel (Ni), lead (Pb), titanium (Ti), or alloys thereof. The backside redistribution layers 192 may perform various functions depending on a design. For example, the backside redistribution layers 192 may include ground (GND) patterns, power (PWR) patterns, signal (S) patterns, and the like. A shape of each of the backside vias 193 may be a tapered shape in the different direction as the vias 143a, 143b, and 143c of the connection member 140.

The passivation layer 150 may protect the connection member 140 from external physical or chemical damage. The passivation layer 150 may have openings exposing at least portions of the third redistribution layer 142c of the connection member 140. The number of openings formed in the passivation layer 150 may be several tens to several thousands. A material of the passivation layer 150 is not particularly limited. For example, an insulating material may be used as the material of the passivation layer 150. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a solder resist may also be used. A backside passivation layer 155 may also be formed on the backside wiring structure 190.

The underbump metal layer 160 may improve connection reliability of the electrical connection structures 165 to thereby improve board level reliability of the fan-out semiconductor package 10A. The underbump metal layer 160 may be connected to the third redistribution layer 142c of the connection member 140 exposed through the openings of the passivation layer 150. The underbump metal layer 160 may be formed in the openings of the passivation layer 150 by the known metallization method using the known conductive material such as a metal, but is not limited thereto.

The electrical connection structures 165 may externally physically and/or electrically connect the fan-out semiconductor package 10A. For example, the fan-out semiconductor package 10A may be mounted on the main board of the electronic device through the electrical connection structures 165. Each of the electrical connection structures 165 may be formed of a conductive material, for example, a solder, or the like. However, this is only an example, and a material of each of the electrical connection structures 165 is not particularly limited thereto. Each of the electrical connection structures 165 may be a land, a ball, a pin, or the like. The electrical connection structures 165 may be formed as a multilayer or single layer structure. When the electrical connection structures 165 are formed as a multilayer structure, the electrical connection structures 165 may include a copper (Cu) pillar and a solder. When the electrical connection structures 165 are formed as a single layer structure, the electrical connection structures 165 may include a tin-silver solder or copper (Cu). However, this is only an example, and the electrical connection structures 165 are not limited thereto.

The number, an interval, a disposition form, and the like, of electrical connection structures 165 are not particularly limited, but may be sufficiently modified depending on design particulars. For example, the electrical connection structures 165 may be provided in an amount of several tens to several thousands, or may be provided in an amount of several tens to several thousands or more or several tens to several thousands or less. When the electrical connection structures 165 are solder balls, the electrical connection structures 165 may cover side surfaces of the underbump metal layer 160 extending onto one surface of the passivation layer 150, and connection reliability may be more excellent.

At least one of the electrical connection structures 165 may be disposed in a fan-out region of the first semiconductor chip 120. The fan-out package may have reliability greater than that of a fan-in package, may implement a plurality of I/O terminals, and may easily perform 3D interconnection. In addition, as compared to a ball grid array (BGA) package, a land grid array (LGA) package, or the like, the fan-out package may be manufactured to have a small thickness, and may have price competitiveness.

The passive component 180 may be disposed on a lower surface of the passivation layer 150 and may be disposed between the electrical connection structures 165. The passive component 180 may be electrically connected to the third redistribution layer 142c. The passive component 180 may include, for example, a surface mounting technology (SMT) component including an inductor, a capacitor, or the like.

Meanwhile, although not illustrated in the drawings, a metal thin film may be formed on the walls of the through-hole 110H, if necessary, in order to radiate heat or block electromagnetic waves.

In addition, a plurality of semiconductor chips performing functions that are the same as or different from each other may be disposed in the through-hole 110H, if necessary. In addition, a separate passive component such as an inductor, a capacitor, or the like, may be disposed in the through-hole 110H, if necessary.

The wiring substrate 210 may be a printed circuit board (PCB) such as an interposer substrate. The wiring substrate 210 may include an insulating layer and a conductive wiring layer formed in the insulating layer. The passivation layer and the like may be formed on opposite surfaces of the wiring substrate 210. A structure and a form of the wiring substrate 210 may be variously changed according to the exemplary embodiments. In addition, in the exemplary embodiments, the interposer substrate may be further disposed between the wiring substrate 210 and the first semiconductor package 100.

The second semiconductor chip 220 may include a plurality of semiconductor chips 221, 222, 223, and 224 which are stacked in parallel to each other. The second semiconductor chip 220 may be attached to the wiring substrate 210 or lower second semiconductor chips 220 by an adhesive member 225. The second semiconductor chip 220 may be electrically connected to the wiring layer 212 of the wiring substrate 210 by conductive wires 240 connected to connection pads 221P. However, in the exemplary embodiments, the second semiconductor chip 220 may also be flip-chip bonded onto the wiring substrate 210.

The second semiconductor chip 220 may also be an integrated circuit (IC) provided in an amount of several hundreds to several millions of elements or more integrated in a single chip. The IC may be a memory chip such as a volatile memory (such as a DRAM), a non-volatile memory (such as a ROM, and a flash memory), or the like, but is not limited thereto. The active surface of the second semiconductor chip 220 refers to a surface of the second semiconductor chip 220 on which the connection pads 221P are disposed, and the inactive surface thereof refers to a surface opposing the active surface. However, according to the exemplary embodiments, the second semiconductor chip 220 may also be disposed in a face-down form. The second semiconductor chip 220 may be formed on the basis of an active wafer. In this case, a base material may be silicon (Si), germanium (Ge), gallium arsenide (GaAs), or the like. Various circuits may be formed in the second semiconductor chip 220. The connection pads 221P may electrically connect the second semiconductor chip 220 to other components, and a conductive material such as aluminum (Al), or the like, may be used as a material of each of the connection pads 221P.

The adhesive member 225 may easily attach the inactive surface of the second semiconductor chip 220 to the lower second semiconductor chips 220 or an upper surface of the wiring substrate 210. The adhesive member 225 may be a tape such as a die attaching film (DAF). A material of the adhesive member 225 is not particularly limited. The adhesive member 225 may include, for example, an epoxy component, but is not limited thereto. The second semiconductor chip 220 may be more stably mounted through the adhesive member 225, and reliability may thus be improved.

The second encapsulant 230 may protect the second semiconductor chip 220. An encapsulation form of the second encapsulant 230 is not particularly limited, but may be a form in which the second encapsulant 230 surrounds at least portions of the second semiconductor chip 220. For example, the second encapsulant 230 may cover at least portions of the active surface of the second semiconductor chip 220, and also cover at least portions of side surfaces of the second semiconductor chip 220. The second encapsulant 230 may include an insulating material. The insulating material of the second encapsulant 230 may be a photo imageable epoxy (PIE), a PID, or the like. However, the insulating material is not limited thereto. That is, a material including an inorganic filler and an insulating resin, for example, a thermosetting resin such as an epoxy resin, a thermoplastic resin such as a polyimide resin, or a resin having a reinforcing material such as an inorganic filler impregnated in the thermosetting resin and the thermoplastic resin, more specifically, an ABF, or the like, may also be used as the insulating material. In addition, the known molding material such as an epoxy molding compound (EMC), or the like, may also be used. Alternatively, a material in which a thermosetting resin or a thermoplastic resin is impregnated in an inorganic filler and/or a core material such as a glass fiber (a glass cloth or a glass fabric) may also be used as the insulating material.

Upper connection terminals 265 may electrically connect the wiring substrate 210 and the backside wiring structure 190 to each other. The upper connection terminals 265 may be interposed between the wiring layer 212 of the wiring substrate 210 and the backside redistribution layers 192 of the backside wiring structure 190. Each of the upper connection terminals 265 may be formed of a conductive material, for example, a solder, or the like. However, this is only an example, and a material of each of the upper connection terminals 265 is not particularly limited thereto. Each of the upper connection terminals 265 may be a land, a ball, a pin, or the like.

FIGS. 10 through 10C are schematic views of an example of a process of bonding a heat radiating member to a first semiconductor chip.

Referring to FIG. 10A, a polishing process may be performed for an inactive surface 120S of the first semiconductor chip 120 and a lower surface 170S of the heat radiating member 170 which are bonded to each other. The polishing process may be, for example, a chemical mechanical polishing (CMP) process. As illustrated, the polishing process may be performed using a polishing machine 300 including a polishing head 320 and a polishing pad 310 attached to the polishing head 320. Since the first semiconductor chip 120 and the heat radiating member 170 are bonded at an atomic level, the first semiconductor chip 120 and the heat radiating member 170 may be polished to have low surface roughness Ra of about 1 nm.

Referring to FIG. 10B, an activation process may be performed for the inactive surface 120S of the first semiconductor chip 120 and the lower surface 170S of the heat radiating member 170. The activation process may be a process for increasing a surface energy state. For example, the activation process may be a process of applying ion bombardment using ions of an inert gas such as argon (Ar) to the inactive surface 120S of the first semiconductor chip 120 and the lower surface 170S of the heat radiating member 170 to thereby break atomic bonds on the surfaces.

Referring to FIG. 10C, a process of closely contacting and pressing the lower surface 170S of the heat radiating member 170 onto the inactive surface 120S of the first semiconductor chip 120 may be performed. By the pressing process, the atoms of the inactive surface 120S of the first semiconductor chip 120 and the lower surface 170S of the heat radiating member 170 may be in close contact with each other and may form bonds at the atomic level. In the pressing process, for example, a pressure of about 100 kN may be applied, but the pressure may be changed depending on sizes of the first semiconductor chip 120 and the heat radiating member 170, and the like.

By the process as described above, the first semiconductor chip 120 and the heat radiating member 170 may be directly bonded to each other without having a separate adhesive layer interposed therebetween. Therefore, a structure and a process of the semiconductor package may be simplified and heat generated from the first semiconductor chip 120 may be more effectively discharged.

FIG. 11 is a schematic cross-sectional view illustrating another example of a fan-out semiconductor package.

Referring to FIG. 11, in a fan-out semiconductor package 10B according to another exemplary embodiment in the present disclosure, the heat radiating member 170 may include first and second heat radiating layers 172 and 174 which are stacked in a vertical direction. The first and second heat radiating layers 172 and 174 may have different thicknesses and may be formed of different materials. For example, a lower first heat radiating layer 172 may include graphite and the second heat radiating layer 174 may include a copper-graphite (Cu-Gr) composite material. Graphite may have anisotropy in thermal conductivity in which the thermal conductivity in a horizontal direction is high, but the thermal conductivity in a vertical direction is low, by a hexagonal mesh structure of carbon atoms. Therefore, high thermal conductivity in the horizontal direction may be secured in a region adjacent to the first semiconductor chip 120 by the first heat radiating layer 172, and thermal conductivity in the vertical direction, that is, in an upward direction may be secured by the second heat radiating layer 174. A thickness T4 of the first heat radiating layer 172 may be smaller than a thickness T5 of the second heat radiating layer 174, but is not limited thereto. A description of other configurations and a manufacturing method except for the abovementioned configuration overlaps that described in the fan-out semiconductor package 10A according to the example described above, and is thus omitted.

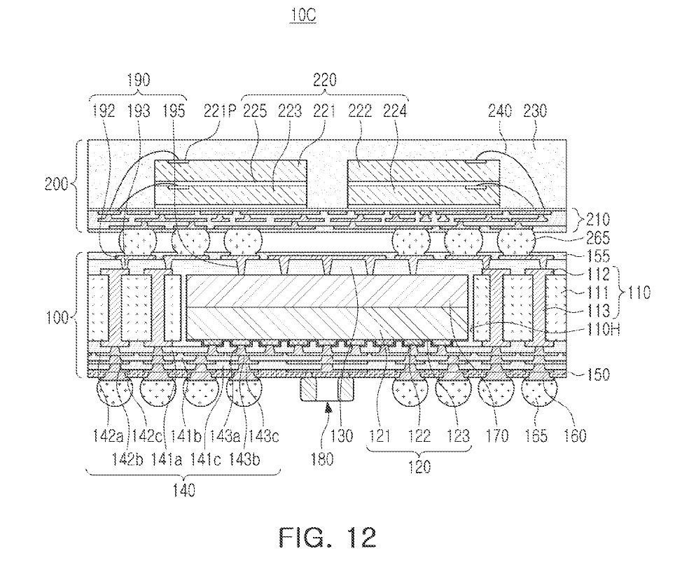

FIG. 12 is a schematic cross-sectional view illustrating another example of a fan-out semiconductor package.

Referring to FIG. 12, in a fan-out semiconductor package 10C according to another exemplary embodiment in the present disclosure, the backside wiring structure 190 may further include heat radiating vias 195 in addition to the backside redistribution layers 192 and the backside vias 193. The heat radiating vias 195 may penetrate through the first encapsulant 130 to connect the backside redistribution layers 192 and the heat radiating member 170 to each other. By the heat radiating vias 195, the heat generated from the first semiconductor chip 120 may be more effectively discharged upwardly from the first semiconductor package 100. An electrical signal may be applied or may not be applied to the heat radiating vias 195. In a case in which the electrical signal is not applied to the heat radiating vias 195, the backside redistribution layers 192 connected to the heat radiating vias 195 may serve as heat radiating pattern layers. A material of each of the heat radiating vias 195 may be the same as that of each of the backside vias 193 and may be different from that of the heat radiating member 170. The material of each of the heat radiating vias 195 may be a conductive material such as copper (Cu), aluminum (Al), silver (Ag), tin (Sn), gold (Au), nickel (Ni), lead (Pb), titanium (Ti), or alloys thereof. A description of other configurations and a manufacturing method except for the abovementioned configuration overlaps that described above, and is thus omitted.

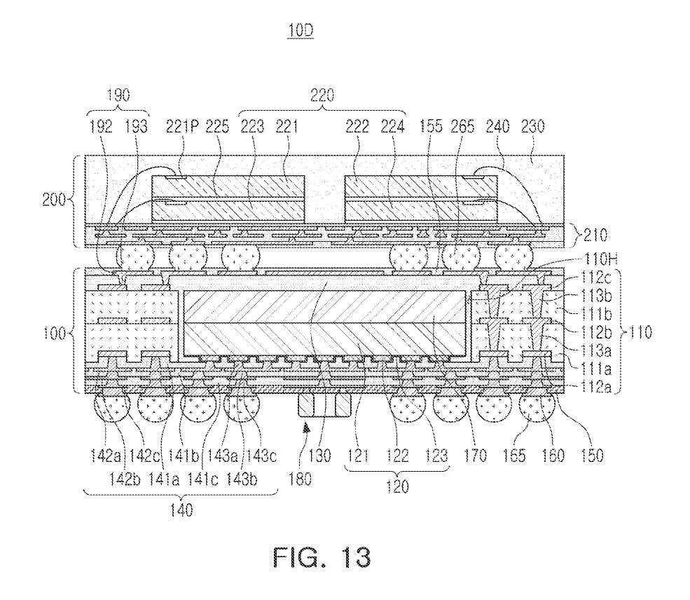

FIG. 13 is a schematic cross-sectional view illustrating another example of a fan-out semiconductor package.

Referring to FIG. 13, in a fan-out semiconductor package 10D according to another exemplary embodiment in the present disclosure, a core member 110 may include a first insulating layer 111a in contact with a connection member 140, a first wiring layer 112a in contact with the connection member 140 and embedded in the first insulating layer 111a, a second wiring layer 112b disposed on the other surface of the first insulating layer 111a opposing one surface of the first insulating layer 111a in which the first wiring layer 112a is embedded, a second insulating layer 111b disposed on the first insulating layer 111a and covering the second wiring layer 112b, and a third wiring layer 112c disposed on the second insulating layer 111b. The first to third wiring layers 112a, 112b, and 112c may be electrically connected to connection pads 122. The first and second wiring layers 112a and 112b and the second and third wiring layers 112b and 112c may be electrically connected to each other through first and second vias 113a and 113b penetrating through the first and second insulating layers 111a and 111b, respectively.

When the first wiring layer 112a is embedded in the first insulating layer 111a, a step generated due to a thickness of the first wiring layer 112a may be significantly reduced, and an insulating distance of the connection member 140 may thus become constant. That is, a difference between a distance from a first redistribution layer 142a of the connection member 140 to a lower surface of the first insulating layer 111a and a distance from the first redistribution layer 142a of the connection member 140 to the connection pad 122 of a first semiconductor chip 120 may be smaller than a thickness of the first wiring layer 112a. Therefore, a high density wiring design of the connection member 140 may be easy.

The lower surface of the first wiring layer 112a of the core member 110 may be disposed on a level above a lower surface of the connection pad 122 of a first semiconductor chip 120. In addition, a distance between a first redistribution layer 142a of the connection member 140 and the first wiring layer 112a of the core member 110 may be greater than that between the first redistribution layer 142a of the connection member 140 and the connection pad 122 of the first semiconductor chip 120. The reason is that the first wiring layer 112a may be recessed into the first insulating layer 111a. As described above, when the first wiring layer 112a is recessed into the first insulating layer 111a, such that the lower surface of the first insulating layer 111a and the lower surface of the first wiring layer 112a have a step therebetween, a phenomenon in which a material of the first encapsulant 130 bleeds to pollute the first wiring layer 112a may be prevented. The second wiring layer 112b of the core member 110 may be disposed between an active surface and an inactive surface of the first semiconductor chip 120. The core member 110 may be formed at a thickness corresponding to that of the first semiconductor chip 120. Therefore, the second wiring layer 112b formed in the core member 110 may be disposed on a level between the active surface and the inactive surface of the first semiconductor chip 120.

Thicknesses of the wiring layers 112a, 112b, and 112c of the core member 110 may be greater than those of the redistribution layers 142a, 142b, and 142c of the connection member 140. Since the core member 110 may have a thickness equal to or greater than that of the first semiconductor chip 120, the wiring layers 112a, 112b, and 112c may be formed at larger sizes depending on a scale of the core member 110. On the other hand, the redistribution layers 142a, 142b, and 142c of the connection member 140 may be formed at sizes relatively smaller than those of the wiring layers 112a, 112b, and 112c for thinness.

A material of each of the insulating layers 111a and 111b is not particularly limited. For example, an insulating material may be used as the material of the insulating layers 111a and 111b. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a PID resin may also be used as the insulating material.

The wiring layers 112a, 112b, and 112c may serve to redistribute the connection pads 122 of the first semiconductor chip 120. A material of each of the wiring layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The wiring layers 112a, 112b, and 112c may perform various functions depending on designs of their corresponding layers. For example, the wiring layers 112a, 112b, and 112c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a, 112b, and 112c may include via pads, wire pads, connection terminal pads, and the like.

The vias 113a and 113b may electrically connect the wiring layers 112a, 112b, and 112c formed on different layers to each other, resulting in an electrical path in the core member 110. A material of each of the vias 113a and 113b may be a conductive material. Each of the vias 113a and 113b may be entirely filled with a conductive material, or a conductive material may also be formed along a wall of each of via holes. In addition, each of the vias 113a and 113b may have all of the shapes known in the related art, such as a tapered shape, a cylindrical shape, and the like. When holes for the first vias 113a are formed, some of the pads of the first wiring layer 112a may serve as a stopper, and it may thus be advantageous in a process that each of the first vias 113a has the tapered shape of which a width of an upper surface is greater than that of a lower surface. In this case, the first vias 113a may be integrated with pad patterns of the second wiring layer 112b. In addition, when holes for the second vias 113b are formed, some of the pads of the second wiring layer 112b may serve as a stopper, and it may thus be advantageous in a process that each of the second vias 113b has the tapered shape of which a width of an upper surface is greater than that of a lower surface. In this case, the second vias 113b may be integrated with pad patterns of the third wiring layer 112c.

Other configurations, for example the contents of the heat radiating member 170 described with reference to FIG. 9 may also be applied to the fan-out semiconductor package 10D according to another exemplary embodiment, and a detailed description thereof is substantially the same as that described in the fan-out semiconductor package 10A described above. Therefore, the detailed description thereof will be omitted.

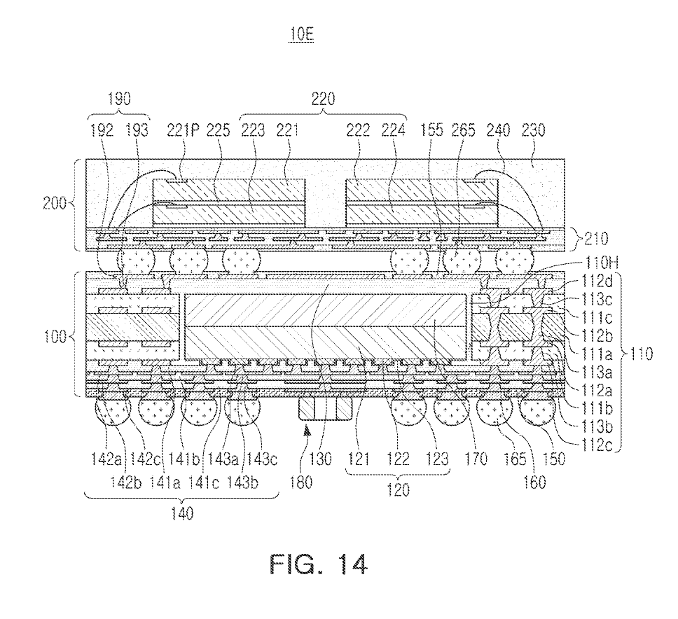

FIG. 14 is a schematic cross-sectional view illustrating another example of a fan-out semiconductor package.

Referring to FIG. 14, in a fan-out semiconductor package 10E according to another exemplary embodiment in the present disclosure, a core member 110 may include a first insulating layer 111a, a first wiring layer 112a and a second wiring layer 112b disposed on opposite surfaces of the first insulating layer 111a, respectively, a second insulating layer 111b disposed on the first insulating layer 111a and covering the first wiring layer 112a, a third wiring layer 112c disposed on the second insulating layer 111b, a third insulating layer 111c disposed on the first insulating layer 111a and covering the second wiring layer 112b, and a fourth wiring layer 112d disposed on the third insulating layer 111c. The first to fourth wiring layers 112a, 112b, 112c, and 112d may be electrically connected to connection pads 122. Since the core member 110 may include a larger number of wiring layers 112a, 112b, 112c, and 112d, a connection member 140 may be further simplified. Therefore, a decrease in a yield depending on a defect occurring in a process of forming the connection member 140 may be suppressed. Meanwhile, the first to fourth wiring layers 112a, 112b, 112c, and 112d may be electrically connected to each other through first to third vias 113a, 113b, and 113c each penetrating through the first to third insulating layers 111a, 111b, and 111c.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF or a PID film including a filler and an insulating resin. However, the materials of the first insulating layer 111a and the second and third insulating layers 111b and 111c are not limited thereto. Similarly, the first vias 113a penetrating through the first insulating layer 111a may have a diameter greater than those of second vias 113b and third vias 113c penetrating through the second and third insulating layers 111b and 111c, respectively.

A lower surface of the third wiring layer 112c of the core member 110 may be disposed on a level below a lower surface of the connection pad 122 of a first semiconductor chip 120. In addition, a distance between a first redistribution layer 142a of the connection member 140 and the third wiring layer 112c of the core member 110 may be smaller than that between the first redistribution layer 142a of the connection member 140 and the connection pad 122 of the first semiconductor chip 120. The reason is that the third wiring layer 112c may be disposed in a protruding form on the second insulating layer 111b, resulting in being in contact with the connection member 140. The first wiring layer 112a and the second wiring layer 112b of the core member 110 may be disposed between an active surface and an inactive surface of the first semiconductor chip 120. The core member 110 may be formed at a thickness corresponding to that of the first semiconductor chip 120. Therefore, the first wiring layer 112a and the second wiring layer 112b formed in the core member 110 may be disposed on a level between the active surface and the inactive surface of the first semiconductor chip 120.

Thicknesses of the wiring layers 112a, 112b, 112c, and 112d of the core member 110 may be greater than those of the redistribution layers 142a, 142b, and 142c of the connection member 140. Since the core member 110 may have a thickness equal to or greater than that of the first semiconductor chip 120, the wiring layers 112a, 112b, 112c, and 112d may also be formed at larger sizes. On the other hand, the redistribution layers 142a, 142b, and 142c of the connection member 140 may be formed at relatively small sizes for thinness.

Other configurations, for example the contents of the heat radiating member 170 described with reference to FIG. 9 may also be applied to the fan-out semiconductor package 10E according to another exemplary embodiment, and a detailed description thereof is substantially the same as that described in the fan-out semiconductor package 10A described above. Therefore, the detailed description thereof will be omitted.

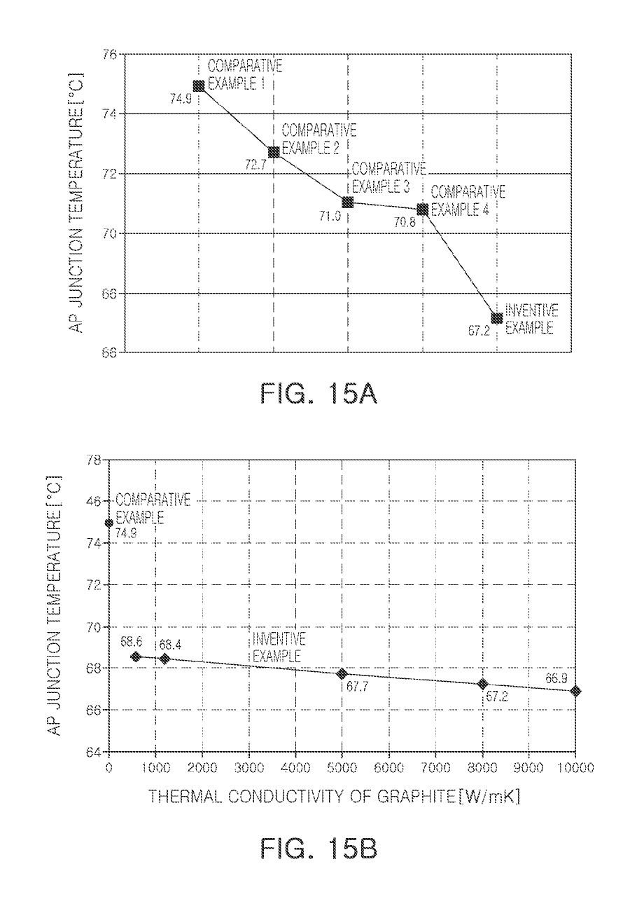

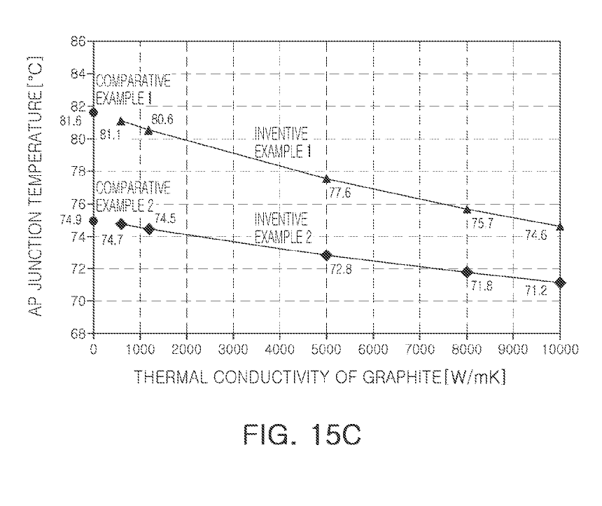

FIGS. 15A through 15C are graphs schematically illustrating a heat radiation effect of a fan-out semiconductor package according to an exemplary embodiment.

Referring to FIG. 15A, results of a simulation of an AP junction temperature for Comparative Examples 1 to 4 and Inventive Example having different conditions of the heat radiating member 170 in the fan-out semiconductor package 10A as illustrated in FIG. are illustrated. The AP junction temperature refers to a temperature at a hot spot in the first semiconductor chip 120, which is an application processor (AP). In the case of Comparative Example 1, a thickness of the first semiconductor chip 120 is 300 μm and the heat radiating member 170 is not provided. In the case of Comparative Example 2, the thickness of the first semiconductor chip 120 is 290 μm and the heat radiating member 170 is formed of copper (Cu) of a thickness of 10 μm. In the case of Comparative Example 3, the thickness of the first semiconductor chip 120 is 150 μm, and the heat radiating member 170 is formed of copper (Cu) of a thickness of 130 μm and is attached to the first semiconductor chip 120 by a die attaching film (DAF) having a thickness of 20 μm. In the case of Comparative Example 4, the thickness of the first semiconductor chip 120 is 150 μm, and the heat radiating member 170 is formed of single crystal silicon carbide (SiC) of a thickness of 130 μm and is attached to the first semiconductor chip 120 by the die attaching film (DAF) having a thickness of 20 μm. In the case of Inventive Example, the thickness of the first semiconductor chip 120 is 150 μm, and the heat radiating member 170 is formed of single crystal silicon carbide (SiC) of a thickness of 150 μm and is directly attached to the first semiconductor chip 120.

As illustrated, as compared to the structure in which the heat radiating member 170 is not provided as in Comparative Example 1, in the case in which the heat radiating member 170 is provided as in Comparative Example 2, the junction temperature is low, and in the case in which the thickness of the heat radiating member 170 is increased as in Comparative Example 3, the junction temperature is also decreased. In the same condition as in Comparative Example 3 and Comparative Example 4, the junction temperature of a case in which silicon carbide (SiC) is used may be lower than that of a case in which copper (Cu) is used. In addition, in a case in which the heat radiating member 170 is directly bonded to the first semiconductor chip 120 as in Inventive Example, the junction temperature may show the lowest temperature of about 670. This is because heat radiation efficiency is improved as an adhesive layer such as the DAF is omitted and heat radiation characteristics may be improved by upwardly raising the thickness of the heat radiating member 170 by a thickness of the omitted adhesive layer.

Referring to FIG. 15B, results of a simulation of an AP junction temperature for Comparative example and Inventive Example having different conditions of the heat radiating member 170 in the fan-out semiconductor package 10B as illustrated in FIG. 11 are illustrated. Comparative Example is for a case in which the thickness of the first semiconductor chip 120 is 300 μm and the heat radiating member 170 is not provided, and Inventive Example is for a case in which the thickness of the first semiconductor chip 120 is 150 μm and the heat radiating member 170 includes a first heat radiating layer 172 formed of graphite having a thickness of 2 μm and a second heat radiating layer 174 formed of a copper-graphite composite material having a thickness of 148 μm. In the case of Inventive Examples, the results obtained by simulating the AP junction temperature while changing a value of thermal conductivity of graphite in a horizontal direction in the range of 500 W/mK to 10000 W/mK are shown. The thermal conductivity of graphite as described above may be varied depending on a measurement direction, a thickness of graphite, a forming method, or the like.

As illustrated, Comparative Example shows the junction temperature of about 75° C., but Inventive Examples show the junction temperature in the range of 66.9° C. to 68.6° C. Therefore, it may be seen in the case of Inventive Examples that heat radiation characteristics are improved by using the heat radiating member 170 of the structure as described above.

Referring to FIG. 15C, results of a simulation of an AP junction temperature for Comparative examples and Inventive Examples having different conditions of the heat radiating member 170 in the fan-out semiconductor package 10A as illustrated in FIG. 9 are illustrated. Comparative Example 1 is for a case in which the thickness of the first semiconductor chip 120 is 160 μm and the heat radiating member 170 is not provided and Inventive Example 1 is for a case in which the thickness of the first semiconductor chip 120 is 158 μm and the heat radiating member 170 is formed of graphite having a thickness of 2 μm. Comparative Example 2 is for a case in which the thickness of the first semiconductor chip 120 is 300 μm and the heat radiating member 170 is not provided and Inventive Example 2 is for a case in which the thickness of the first semiconductor chip 120 is 298 μm and the heat radiating member 170 is formed of graphite having a thickness of 2 μm. In the case of Inventive Examples, the results obtained by simulating the AP junction temperature while changing a value of thermal conductivity of graphite in a horizontal direction in the range of 500 W/mK to 10000 W/mK are shown.

As illustrated, Comparative Example 1 shows the highest junction temperature and Inventive Example 1 shows the junction temperature lower than that of Comparative temperature 1. Comparative Example 2 shows the junction temperature lower than that of Comparative Example 1 and Inventive Example 2 shows the junction temperature lower than that of Comparative Example 2. As described above, in the case in which the thickness of the first semiconductor chip 120 is relatively thin, a relatively high junction temperature appears. However, as the thermal conductivity of the material used as the heat radiating member 170 is larger, a difference in the junction temperature according to the thickness of the first semiconductor chip 120 is decreased. Therefore, the thickness of the first semiconductor chip 120 has an influence on a heat radiation effect, but in a case in which the thermal conductivity of the heat radiating member 170 is high even though the thickness of the first semiconductor chip 120 is relatively thin, it may be seen that the heat radiation effect close to a case in which the thickness of the first semiconductor chip 120 is thick may appear.

Herein, a lower side, a lower portion, a lower surface, and the like, are used to refer to a direction toward a mounted surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” means the concept including a physical connection and a physical disconnection. It can be understood that when an element is referred to with “first” and “second”, the element is not limited thereby. They may be used only for a purpose of distinguishing the element from the other elements, and may not limit the sequence or importance of the elements. In some cases, a first component may be named a second component and a second component may also be similarly named a first component, without departing from the scope of the present disclosure.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

As set forth above, according to the exemplary embodiment in the present disclosure, a fan-out semiconductor package of which heat radiation characteristics are improved may be provided.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a core member having a through-hole;
a semiconductor chip disposed in the through-hole of the core member and having an active surface on which connection pads are disposed and an inactive surface disposed to oppose the active surface;
a heat radiating member directly bonded to the inactive surface of the semiconductor chip;
an encapsulant encapsulating at least a portion of the semiconductor chip; and
a connection member disposed on the active surface of the semiconductor chip and including redistribution layers electrically connected to the connection pads of the semiconductor chip.

2. The fan-out semiconductor package of claim 1, wherein the heat radiating member includes at least one of silicon carbide (SiC), graphite, and a metal-graphite composite material.

3. The fan-out semiconductor package of claim 1, wherein the heat radiating member has a coefficient of thermal expansion in the range of 2 ppm/K to 10 ppm/K.

4. The fan-out semiconductor package of claim 1, wherein the heat radiating member has the same size as that of the semiconductor chip on a plane and is in direct contact with an entirety of the inactive surface of the semiconductor chip.

5. The fan-out semiconductor package of claim 1, wherein the heat radiating member is positioned in the through-hole.

6. The fan-out semiconductor package of claim 1, wherein the heat radiating member includes first and second heat radiating layers, sequentially stacked on the semiconductor chip.

7. The fan-out semiconductor package of claim 6, wherein the first heat radiating layer includes graphite, and
the second heat radiating layer includes a metal-graphite composite material.

8. The fan-out semiconductor package of claim 1, wherein the heat radiating member has thermal conductivity higher than that of silicon (Si).

9. The fan-out semiconductor package of claim 8, wherein the heat radiating member has thermal conductivity in the range from 250 W/mK to 500 W/mK.

10. The fan-out semiconductor package of claim 1, wherein a thickness the heat radiating member is equal to or smaller than that of the semiconductor chip.

11. The fan-out semiconductor package of claim 1, further comprising:
backside redistribution layers disposed on the encapsulant; and
heat radiating vias penetrating through the encapsulant and connecting the backside redistribution layers and the heat radiating member to each other.

12. The fan-out semiconductor package of claim 1, further comprising a passive component attached to a lower surface of the connection member.

13. The fan-out semiconductor package of claim 1, wherein the core member includes a first core insulating layer, a first wiring layer in contact with the connection member and embedded in the first core insulating layer, and a second wiring layer disposed on the other surface of the first core insulating layer opposing one surface of the first core insulating layer in which the first wiring layer is embedded, and
the first and second wiring layers are electrically connected to the connection pads.

14. The fan-out semiconductor package of claim 1, wherein the core member includes a first core insulating layer, and a first wiring layer and a second wiring layer disposed on opposite surfaces of the first core insulating layer, and
the first and second wiring layers are electrically connected to the connection pads.

15. A fan-out semiconductor package comprising:
a first semiconductor package including a core member having a through-hole, a first semiconductor chip disposed in the through-hole of the core member and having an active surface on which connection pads are disposed and an inactive surface disposed to oppose the active surface, a heat radiating member directly bonded to the inactive surface of the first semiconductor chip, a first encapsulant encapsulating at least a portion of the first semiconductor chip, and a connection member disposed on the active surface of the first semiconductor chip and including redistribution layers electrically connected to the connection pads of the first semiconductor chip; and
a second semiconductor package including a wiring substrate disposed on the first semiconductor package and electrically connected to the connection member through connection terminals, at least one second semiconductor chip disposed on the wiring substrate, and a second encapsulant encapsulating at least a portion of the second semiconductor chip.

16. The fan-out semiconductor package of claim 15, wherein the heat radiating member has a coefficient of thermal expansion in the range of 2 ppm/K to 10 ppm/K.

17. The fan-out semiconductor package of claim 1, wherein the heat radiating member includes
a first radiating layer bonded directly to the inactive surface of the semiconductor chip, the first radiating layer comprising a material having anisotropic thermal conductivity and being disposed such that an axis having lower thermal conductivity is along a direction from the active surface to the inactive surface; and
a second radiating layer bonded directly to the first radiating layer.

18. The fan-out semiconductor package of claim 1, wherein the heat radiating member includes
a first heat radiating layer comprising graphite disposed such that sheets of graphite are stacked along a direction extending from the active surface to the inactive surface of the semiconductor chip, the first radiating layer being bonded directly to the inactive surface; and
a second heat radiating layer comprising a metal-graphite composite disposed on the first heat radiating layer.
